(19) United States
(12) Patent Application Publication
(10) Pub. No.: US 2008/0299293 A1
(43) Pub. Date: Dec. 4, 2008

(54) SOLVENT SYSTEM FOR CONJUGATED POLYMERS

(75) Inventors: Elena Sheina, Pittsburgh, PA (US); Darin Laird, Pittsburgh, PA (US); Caton Goodman, North Huntingdon, PA (US)

Correspondence Address: FOLEY AND LARDNER LLP;SUITE 500, 3000 K STREET NW, WASHINGTON, DC, 20007, US

(73) Assignee: Plextronics, Inc.

(21) Appl. No.: 12/113,058

(22) Filed: Apr. 30, 2008

Related U.S. Application Data
(60) Provisional application No. 60/915,632, filed on May 2, 2007.

(51) Int. Cl. C08F 28/06; C08K 3/04; B05D 5/12

(52) U.S. Cl. 427/58; 526/256; 524/495

(57) ABSTRACT

A solvent system for a conjugated polymer that includes at least two different solvents, at least one first solvent and at least one second solvent wherein the second solvent comprises a heterocyclic ring to improve the characteristics of materials made therefrom. Use of the solvent system to improve the electronic and/or optoelectronic characteristics of materials that include conjugated polymers, such as polythiophenes, optionally including n-acceptors, which are cast from a composition that includes the solvent system. In some embodiments the improved characteristics include higher absorption of solar radiation, increased current densities and higher power conversion efficiencies. As a result, materials made with the present solvent systems are well-suited for use in a variety of electronic devices including, photovoltaic cells, light emitting diodes, and transistors.

### RELATED APPLICATIONS

This application claims priority to U.S. provisional application Ser. No. 60/915,632, filed May 2, 2007, to Sheina et al., which is incorporated herein by reference in its entirety.

### BACKGROUND

Organic materials are providing exciting prospects for applications in electronic devices including, for example, printed electronics, solar cells, light-emitting diodes, and thin film transistors, among others. In particular, solar cells (or photovoltaic devices) are important because an economic need exists for a practical source of renewable energy that will genuinely reduce dependence upon fossil fuels. Silicon-based solar energy systems have been touted for years as a potential candidate. However, the capital-intensive nature of silicon manufacturing processes contributes to a cost structure that falls significantly short of commercial success. Photovoltaic cells, or solar cells, based on Inherently Conductive Polymers (ICPs) (or conducting polymers or conjugated polymers such as polyacetylene, polythiophene, polyaniline, polypyrrole, polyfluorene, polyphenylene, or poly(phenylene vinylene) offer great potential as significantly lower cost devices because these polymers can be handled like inks in conventional printing processes.

Alternative sources of energy, especially renewable energy, are being sought to dramatically change the functional and cost boundaries resulting from current energy sources. This need is heightened by the rapidly increasing cost, environmental impact, and geo-political implications of the world's reliance on fossil fuels. Regulations from the global (e.g., Kyoto) to local level increase the demand for cost-effective renewable energy supply. The use of the sun's rays to create power represents an attractive, zero-emission source of renewable energy.

Silicon-based solar cells, first demonstrated over 50 years ago (Perlin, John “The Silicon Solar Cell Turns 50” NREL 2004), are the primary technology in the current $5 billion solar cell market. However, the installed cost of this technology is approximately five to ten times that of traditional power sources. Thus, its cost/performance structure does not facilitate broad market adoption. As a result, solar energy accounts for much less than 1 percent of the nation's current energy supply. In order to expand this reach, and meet the growing need for renewable energy sources, novel alternative technologies are required.

Conductive polymers are a key component of a new generation of solar cell that promises to significantly reduce the cost/performance barrier of existing solar cells. The primary advantage of a conductive polymer solar cell is that the core materials and the device itself can be manufactured in a low-cost manner. The core materials—similar to plastics—are made in industrial sized reactors under standard thermal conditions. They can be solution processed to form thin films or printed by standard printing techniques. Thus, the cost of a manufacturing plant is orders of magnitudes less expensive than a silicon fabrication facility. This creates a low total-cost solar cell manufacturing platform. Furthermore, conductive polymer solar technology presents flexible, light weight design advantages compared to silicon-based solar cells. While this technology holds great promise, commercialization hurdles remain. A need exists to find compositions and processing conditions which substantially improve performance, hopefully with minimal changes in composition.

### SUMMARY

Compositions, methods of making, methods of using, and devices and articles are described herein.

For example, provided herein is a composition comprising at least one conjugated polymer, at least one first solvent, and at least one second solvent, wherein the second solvent is different from the first solvent, wherein the second solvent comprises a heterocyclic ring, and further wherein the volume ratio of second solvent to first solvent is about 1:99 to 99:1, desirably at least about 1:1.

In another embodiment, a composition is provided comprising at least one conjugated polymer comprising a backbone repeat unit comprising a first heterocyclic ring, at least one first solvent, and at least one second solvent, wherein the second solvent is different from the first solvent and the second solvent comprises a second heterocyclic ring, wherein the first heterocyclic ring and the second heterocyclic ring are the same. In this embodiment, the first and second heterocyclic rings may have the same substituents or different substituents.

Another embodiment provides a composition comprising at least one soluble conjugated polymer, at least one first solvent for the soluble conjugated polymer which has a boiling point of about 50° C. to about 210° C., at least one second solvent which comprises a heterocyclic ring and is different from the first solvent and has a boiling point of about 85° C. to about 210° C.

Advantages include improved ordering of polymeric chains and polymer morphology, improved morphology of the blend, increased polymer solubility and processability, improved solar cell performance including improved efficiency, and versatility in that improvements can be found with different conjugated polymers.

### BRIEF DESCRIPTION OF THE DRAWINGS

FIG. 1. shows the UV-Vis-NIR spectra of aryl-substituted polythiophene in solid state as spin cast from chloroform (CHCl₃) (dash line, λₘₐₓ=545 nm) and from CHCl₃:3-methyl thiophene (3MTh) (90:10 ratio) (solid line, λₘₐₓ=558 nm).

FIG. 2 shows I-V characteristics of an organic photovoltaic (OPV) cell with the active layer prepared from poly(3-hexylthiophene) (P3HT) and a soluble fullerene (1.2:1) cast from: (a) a blend of dichlorobenzene and 3-methylthiophene (75:25); (b) dichlorobenzene.

### DETAILED DESCRIPTION

### Introduction and Definitions

In practicing the presently claimed inventions in their various embodiments, the following description of the technical literature and the various components can be used. The references cited throughout the specification including the list at the end are hereby incorporated by reference in their entirety.

Provisional patent application Ser. No. 60/612,640 filed Sep. 24, 2004 to Williams, et al. (“HETEROATOMIC REGIOREGULAR POLY(3-SUBSTITUTED THIOPHENES) FOR ELECTROLUMINESCENT DEVICES”), and U.S. Ser. No. 11/234,374 filed Sep. 26, 2005, are hereby incorporated by reference in their entirety including the description of the polymers, the figures, and the claims.

Provisional patent application Ser. No. 60/612,641 filed Sep. 24, 2004, to Williams, et al. (“HETEROATOMIC REGIOREGULAR POLY (3-SUBSTITUTED THIOPHENES) FOR PHOTOVOLTAIC CELLS”), and U.S. Ser. No. 11/234,373 filed Sep. 26, 2005 are hereby incorporated by reference in their entirety including the description of the polymers, the figures, and the claims.

Provisional patent application Ser. No. 60/651,211 filed Feb. 10, 2005, to Williams, et al. (“HOLE INJECTION LAYER COMPOSITIONS”), and U.S. Ser. No. 11/350,271 filed Feb. 9, 2006, are hereby incorporated by reference in their entirety including the description of the polymers, the figures, and the claims.

Priority provisional patent application Ser. No. 60/661,934 filed Mar. 16, 2005, to Williams, et al., and U.S. Ser No. 11,376/550 filed Mar. 16, 2006 are hereby incorporated by reference in their entirety including the description of the polymers, the figures, and the claims.

U.S. Provisional application 60/812,961 filed Jun. 13, 2006 (“Organic Photovoltaic Devices Comprising Fullerenes and Derivatives Thereof”) is hereby incorporated by reference in its entirety including disclosure for active layer compositions. US Regular Application, “Organic Photovoltaic Devices Comprising Fullerenes and Derivatives Thereof,” Ser. No. 11/743,587 filed on May 2, 2007 to Laird et al., is also hereby incorporated by reference in its entirety including, but not limited to, the disclosure of active layer compositions.

Solar cells are described in for example Hoppe and Sariciftci, J. Mater. Res., Vol. 19, No. 7, July 2004, 1924-1945, which is hereby incorporated by reference including the figures.

“Optionally substituted” groups refers to functional groups that may be substituted or unsubstituted by additional functional groups. When a group is unsubstituted by an additional group is referred to as the group name, for example alkyl or aryl. When a group is substituted with additional functional groups it may more generically be referred to as substituted alkyl or substituted aryl.

“Aryl” refers to a cyclic, aromatic arrangement of carbon atoms forming a ring. This term is exemplified by groups such as phenyl, biphenyl, anthracenyl, and naphthenyl. Aryl groups include groups containing condensed rings, such as naphthalene.

“Heterocyclic” refers to a saturated, unsaturated, or heteroaromatic group having a single ring or multiple condensed rings, said ring or rings containing carbon atoms and at least one heteroatom, such as nitrogen, oxygen and sulfur. If a heterocyclic ring contains two or more heteroatoms, the heteroatoms may be the same or different. The ring or rings may be aromatic or non-aromatic. Any reference to two or more entities having the same heterocyclic ring indicates that the atoms of the ring are the same, but not necessarily the substituents attached to the rings. The heterocyclic rings may have, for example, 1 to 20 carbon atoms and from, for example, 1 to 4 hetero atoms, such as nitrogen, oxygen, and sulfur within the ring.

“Alkyl” refers to straight chain, branched and cyclic alkyl groups. Preferred alkyl groups may have, for example, 1 to 20 carbon atoms, or from 1 to 15 carbon atoms, or from 1 to 10, or from 1 to 5, or from 1 to 3 carbon atoms. This term is exemplified by groups such as methyl, ethyl, n-propyl, iso-propyl, n-butyl, t-butyl, n-pentyl, ethylhexyl, dodecyl, iso-pentyl, and the like. The phrase also includes cyclic alkyl groups such as cyclopropyl, cyclobutyl, cyclopentyl, cyclohexyl, cycloheptyl, and cyclooctyl. The phrase alkyl includes primary alkyl groups, secondary alkyl groups, and tertiary alkyl groups.

“Alkoxy” refers to the group “alkyl-O—” which includes, by way of example, methoxy, ethoxy, n-propyloxy, iso-propyloxy, n-butyloxy, t-butyloxy, n-pentyloxy, 1-ethylhex-1-yloxy, dodecyloxy, isopentyloxy, and the like.

“Aryloxy” refers to the group aryl-O— that includes, by way of example, phenoxy, naphthoxy, 4-chlorophenyloxy, 2-methylphenyloxy and the like.

“Alkenyl” refers to alkenyl group preferably having from 2 to 6 carbon atoms and more preferably 2 to 4 carbon atoms and having at least 1 and preferably from 1-2 sites of alkenyl unsaturation. Such groups are exemplified by vinyl, allyl, but-3-en-1-yl, and the like.

“Alkylene” refers to straight chain and branched divalent alkyl groups. Preferred alkylenes may have, for example, from 1 to 20 carbon atoms, or from 1 to 15 carbon atoms, or from 1 to 10 carbon atoms, or from 1 to 3 carbon atoms. This term is exemplified by groups such as methylene, ethylene, n-propylene, iso-propylene, n-butylene, t-butylene, n-pentylene, ethylhexylene, dodecylene, isopentylene, and the like.

“Alkylene Oxide” refers to a -[alkylene-O]ₙ group, where n may be, for example, an integer from 1 to 10, or from 1 to 5, or from 1 to 3.

The solvent system can include at least one first solvent and at least one second solvent, wherein the second solvent, which can be present in a smaller amount (as measured by volume percent) than the first solvent, includes a heterocyclic ring. Without wishing or intending to be bound to any particular theory, the improved characteristics of polymer materials cast from compositions that include the solvent system may be due to the ability of the second solvent to increase, upon solvent removal, the intermolecular and/or intramolecular order of the polymers to provide polymer materials having improved morphologies and/or packing densities.

### Conjugated Polymer

Electrically conductive or conjugated polymers are described, for example, in The Encyclopedia of Polymer Science and Engineering, Wiley, 1990, pages 298-300, including polyacetylene, poly(p-phenylene), poly(p-phenylene sulfide), polypyrrole, and polythiophene, which is hereby incorporated by reference in its entirety. This reference also describes blending and copolymerization of polymers, including block copolymer formation.

Recently there has been much interest in the incorporation of ICPs into organic electronics devices (see, e.g., Braun, D., Materials Today, 2002, June, 32-39, Dimitrakopoulos, IBM J. Res. & Dev., 2001, 45, No. 1, 11-27 and references cited therein). These applications function via the exploitation of the electrical and optical properties of the ICPs that arise from their (a) conjugated structure, (b) functionality, and (c) conformation (in solution) or morphology (in the solid state).

In applications such as polymer-based solar cells, polymer light emitting diodes, organic transistors, or other organic circuitry the flow of electrons and positive conductors (i.e., “holes”) is dictated by the relative energy gradient of the conduction and valence bands within the components. Therefore, suitable ICPs for a given application are selected for the values of their energy band levels which may be suitably approximated through analysis of ionization potential (as measured by cyclic voltammetry) Micaroni, L., et al., J. Solid State Electrochem., 2002, 7, 55-59 and references sited therein) and band gap (as determined by UV/Vis/NIR spectroscopy as described in Richard D. McCullough, Adv. Mater., 1998, 10, No. 2, pages 93-116, and references cited therein). Examples of ICPs suitable for use in the present compositions include, but are not limited to, polythiophene, polypyrrole, polyaniline, polyfluorene, polypheneylene, polyphenylene vinylene, and derivatives, copolymers and mixtures thereof.

Synthetic methods, doping, and polymer characterization, including regioregular polythiophenes with side groups and block copolymers, is provided in, for example, U.S. Pat. No. 6,602,974 to McCullough, et al. and U.S. Pat. No. 6,166,172 to McCullough, et al., which are hereby incorporated by reference in their entirety. Additional description can be found in the article, “The Chemistry of Conducting Polythiophenes,” by Richard D. McCullough, Adv. Mater., 10, No. 2, pages 93-116, and references cited therein, which is hereby incorporated by reference in its entirety. Another reference which one skilled in the art can use is the Handbook of Conducting Polymers, 2.sup.nd Ed., 1998, Chapter 9, by McCullough, et al., “Regioregular, Head-to-Tail Coupled Poly(3-alkylthiophene) and its Derivatives,” pages 225-258, which is hereby incorporated by reference in its entirety. Polythiophenes are described for example in Roncali, J., Chem. Rev., 1992, 92, 711; Schopf, et al., Polythiophenes: Electrically Conductive Polymers, Springer: Berlin, 1997.

In one embodiment, the conjugated polymer can comprise both conjugated segments and non-conjugated segments including a block copolymer, including AB type and ABA type.

The conjugated polymer can comprise at least one backbone repeat unit comprising a heterocyclic ring. In particular, the conjugated polymer can comprise at least one backbone repeat unit comprising a thiophene ring. In particular, the conjugated polymer can comprise a regioregular polythiophene, wherein at least some of the thiophene rings are substituted.

Regioregularity of polymers is known in the art and the degree of regioregularity can be for example at least about 70%, at least about 80%, at least about 90%, at least about 95%, at least about 98%, or at least about 99%.

Polythiophenes are particularly well-suited for the present applications because polythiophenes have a conjugated π-electron band structure that makes them strong absorbers of light in the visible spectrum and hence a candidate p-type semiconductor for photovoltaic cells. The polythiophenes, for example, may have the following structure:

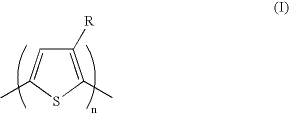

where R is a substituent and n represents the number of repeat units of Formula I in the polymer backbone. The thiophene repeat units may be adjacent (as in a homopolymer) or may be separated by other backbone units (as in a copolymer). Typically, n has a value of about 5 to about 1,500, desirably about 50 to about 1,000.

In some embodiments R may be an unsubstituted or substituted alkyl group, an unsubstituted or substituted alkoxy group or aryloxy group. In such embodiments, possible substituents for the alkyl group or alkoxy group include hydroxyl, phenyl, and additional unsubstituted or substituted alkoxy groups, where these alkoxy substituents are in turn optionally substituted with hydroxyl, phenyl or alkoxy groups.

In other embodiments, R may be an unsubstituted or substituted alkylene oxide group or a substituted lower alkylene where the lower alkylene group is substituted with an unsubstituted or substituted alkylene oxide group. Possible substituents for the alkylene oxide groups are hydroxyl, phenyl, ether and alkoxy groups.

In other embodiments, R may be an unsubstituted or substituted ethylene oxide-based group, an unsubstituted or substituted propylene oxide-based group, substituted methylene, or substituted ethylene. In such embodiments, the methylene and ethylene group may be substituted with unsubstituted or substituted ethylene oxide or unsubstituted or substituted propylene oxide groups. Possible substituents for the substituted ethylene oxide and substituted propylene oxide groups include hydroxyl, phenyl, and additional alkoxy groups.

By way of illustration, the conjugated polymer may be a poly(alkyl thiophene), a poly(aryl thiophene), poly(ether thiophene) or a poly(alkoxy thiophene). More specifically, the polythiophene may be a poly(3-alkyl thiophene), a poly(3-aryl thiophene), a poly(3-ether thiophene) or a poly(3-alkoxy thiophene).

The heterocyclic rings may optionally include additional substituents. For example, a 3-substituted thiophene ring, as described above, may optionally include additional substituents at other ring positions. Such additional substituents include, but are not limited to, H, Cl, Br, I, F, optionally substituted alkyl, optionally substituted aryl, optionally substituted alkylaryl, optionally substituted alkoxy, optionally substituted aryloxy, optionally substituted alkylene oxide, optionally substituted alkylene, functionalized alkyl, functionalized aryl, functionalized alkylaryl, functionalized alkoxy, functionalized aryloxy. functionalized alkylene oxide, or functionalized alkylene. Therefore, these additional substituents may be linear, branched, heteroatomic substituted, oligomeric, polymeric, or may contain one or more halogen, hydroxyl, carboxylic acid, amide, amine, nitrile, ether, ester, thiol, thioether, and like groups.

Polythiophenes can be prepared by various chemical and electrochemical transformations of suitably substituted thiophenes that result, primarily in the coupling of the thiophene rings at the 2- and 5-positions of the monomer. The degree of other modes of coupling of these thiophene moieties depends on the method employed and can afford polymers and/or oligomers of varying regioregularity. Examples of specific polythiophenes, including poly(3-substituted thiophenes), regioregular poly(3-substituted thiophenes), substituted polythiophenes, and random copolymers thereof, and methods for their production are described in greater detail in, for example, U.S. patent application Ser. No. 11/376,550.

The polymer content of the composition can be varied to achieve the best electronic or optoelectronic properties and processing.

### Solvents

The solvent system can include at least two solvents, at least one first solvent and at least one second solvent, which are different from each other. They can be organic solvents.

The first solvent can be a solvent selected to dissolve the conjugated polymer, or at least provide a stable dispersion of conjugated polymer. The first solvent can lack a heterocyclic ring and may be, for example, an aromatic solvent or compound, a halogenated aromatic solvent or compound, or a chlorinated solvent, including chlorinated aromatic solvents. Examples of first solvents include, but are not limited to, chlorobenzene, 1,2-dichlorobenzene, chloroform, 1,2-dichloroethane, dichloromethane, carbon tetrachloride, toluene, xylene (e.g., o-xylene), cyclohexanone, ethylacetate, cresol, butyrolacetone, and dimethylformamide, and combinations thereof.

The second solvent differs from the first solvent and comprises at least one heterocyclic ring. The heterocyclic ring can be for example at least one thiophene ring. The second solvent can be for example an alkylthiophene. In some instances the heterocyclic ring is not a nitrogen-containing ring. Thus, in some embodiments the second solvent is not a pyridine, pyrazine, pyrimidine, or a pyrrolidinone. In some embodiments, the heterocyclic ring includes at least one S atom and at least one O atom. The second solvent can be a compound that is a liquid at room temperature and pressure so that it can be easily removed in film formation. If the second solvent is almost a liquid or not a liquid at room temperature and pressure, then it can be selected to be removable by methods known in the art during film formation. Examples of suitable second solvents include, but are not limited to, thiophene derivatives (i.e., substituted thiophenes). The thiophene ring may be substituted or unsubstituted in different positions on the ring. However, in some instances the thiophene derivatives do not contain halogen atoms. Alkylthiophenes and combinations thereof may be used as the second solvent. The alkyl group can be for example C1, C2, C3, C4, and the like up to and including C8, C12, C16, and C20. The alkyl group can be linear or branched. Specific examples of suitable alkylthiophenes include methylthiophene, ethylthiophene, propylthiophene, butylthiophene, pentythiophene, hexylthiophene, heptylthiophene, octylthiophene, nonylthiophene, and decylthiophene.

One preferred embodiment for the second solvent can be represented as:

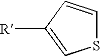

where R′ is an alkyl group at the 3-position, and R′ can be for example a C1 to C20, or C1 to C10 alkyl group such as methyl or hexyl. Alternatively, S could be replaced with another heteroatom such as N or O. An alkyl group can be functionalized or substituted with for example one functional or substituent group to the extent this change is compatible with the applications and other components in the ink. In addition, substituents can be included in the 2, 4, or 5 position of the heterocyclic ring.

The second solvent can comprise oligomers of heterocyclic rings to the extent these oligomers can function as a solvent. For example dimers, trimers, or tetramers can be used including dimers, trimers, tetramers of thiophenes.

The composition may optionally include additional solvents, including additional first solvents lacking a heterocyclic ring and additional second solvents having a heterocyclic ring. Thus, the solvent system may include two or more (e.g., three or more) heterocyclic compounds, e.g., thiophene compounds, along with the first solvent. Where the solvent system includes two or more solvents having heterocyclic rings, the heterocyclic rings in those solvents may be the same or different.

The solvents should have melting points that are sufficiently low that they are liquids at room temperature (e.g., melting points of 20° C., or less) and should have boiling points that are sufficiently low to allow films cast from compositions containing the solutions to dry in a reasonable time, including with use of annealing, vacuum, or spin-coating methods. Typically, the solvents will have boiling points from about 50° C. and about 250° C. The melting and boiling points for the at least two solvents may be similar or different. For example, in some solvent systems one or both of the first solvent and the second solvent will both have a boiling point at atmospheric pressure of no more than about 135° C., no more than about 130° C., or no more than about 125° C. Alternatively, one or both of the first and second solvents may have a boiling point of greater than 135° C. at atmospheric pressure. This includes embodiments where the first and second solvents both have boiling points of at least 140° C. The first solvent may be chosen such that it has a boiling point that is higher than or lower than that of the second solvent.

If the conjugated polymer of the composition includes a heterocyclic repeat backbone unit, it may be advantageous to select a second solvent having the same heterocyclic ring as the repeat backbone unit. Thus, one or more thiophene compounds may be used as the second solvent in a composition that includes a polythiophene. The conjugated polymer can comprise at least one backbone repeat unit comprising a heterocyclic ring, wherein the heterocyclic ring in the backbone repeat unit and the heterocyclic ring in the second solvent can be the same. For example, each ring can be a thiophene ring. The substituents of each ring can be alkyl substituents and can be the same or different. For example, the conjugated polymer can comprise polythiophene and the second solvent can comprise a thiophene.

Alternatively, the heterocyclic rings of the repeat backbone unit and the heterocyclic ring of the second solvent may be different. For example, the rings may differ in one or more of the following characteristics: (1) types of heteroatoms in the ring; (2) number of atoms in the ring; and (3) number of double bonds in the rings.

### Solvent Amounts

The amounts of the first and second solvents in the system may vary over a wide range. For example, the ratio of first solvent to second solvent may range from about 1:99 to 99:1 (e.g., about 1:4 to 4:1). The amount of the first solvent can be larger by volume than the amount of the second solvent. For example, the volume ratio of the second solvent to the first solvent can be, for example, less than about 1:1, or less than about 1:2, or less than about 1:3. The lower amount of second solvent can vary with the compounds, but can be for example a volume ratio of second solvent to first solvent of at least about 1:10, or at least about 1:25, or at least about 1:50. One skilled in the art can vary the amount of the two solvents to achieve the desired properties in the device.

If more than one first solvent is present, then the amounts of each of the first solvents are combined for use in determining the total amount of first solvent. If more than one second solvent is present, then the amounts of each of the second solvents are combined for use in determining the total amount of second solvent. For example, if one second solvent is used in an amount of 10 mL, and combined with 10 mL of another second solvent, the total amount of second solvent added is 20 mL. If the solvent system includes more than one first solvent lacking a heterocyclic ring and/or more than one second solvent containing a heterocyclic ring, the total volume percent of those solvents that lack a heterocyclic ring can be greater than the total volume percent of those solvents that have a heterocyclic ring. As such, those solvents that contain a heterocyclic ring can be considered co-solvents in the system.

The compositions comprising the at least two solvents and the conjugated polymer can comprise about 1 volume percent (vol. %) solids or less, or about 0.1 vol. % solids or less.

The solvents and conjugated polymer, as inks, can be formulated or adapted for use in a particular application such as a solar cell including use of additional components such as electron acceptors. The additional components and solvents can be adapted to provide good dispersability, solubility, and stability. For example, solvents can be used which provide good solubility or dispersability for fullerenes or fullerene derivative compounds.

One important embodiment is to avoid use of solvents in amounts which prevent solubility or dispersability for the fullerene derivative.

### Electron Acceptors

Optionally, the composition may include an n-type component or electron acceptor, or an electron acceptor moiety. These are materials with a strong electron affinity and good electron accepting character. The n-type component should provide fast transfer, good stability, and good processability. The n-type material is desirably soluble in, dispersible in, or otherwise miscible with the solvents in order to provide for solution processing. The n-type component may take the form of particles, including microparticles and nanoparticles, inorganic particles, organic particles, and/or semiconductor particles. The n-type component can be a molecular material, or a non-polymeric material, having a molecular weight less than about 2,000 g/mol or less than about 1,000 g/mol. The n-type component can be any component providing a p/n composite, such as a bulk heterojunction structure, with the conjugated polymer. Specific examples of n-type components or moieties include, but are not limited to, fullerenes, fullerene derivatives, soluble fullerene derivatives, carbon nanotubes, electron-accepting metal oxides such as titanium dioxide and zinc oxide, cadmium selenide, and perylenes or perylene derivatives. Methanofullerene[6,6]-phenyl C₆₁-butyric acid methyl ester (PCBM), C₆₀-indene mono adduct, and C₆₀-indene bis-adduct are preferred examples, of n-type components.

The weight ratio between the conjugated polymer and the n-type component in the composition can be controlled to achieve the desired electronic or optoelectronic (e.g., photovoltaic) effect. For example, the weight ratio of the polymer to n-type component in the composition may be about 10:1 to about 0.5:1. This includes embodiments where the weight ratio is about 9:1 to 1:1 and further includes embodiments where the weight ratio is about 3:1 to about 1:1. Another range is about 1:2 to about 2:1. The amount can be tailored with one or more other parameters such as for example molecular weight, solvent selection, casting or coating conditions, and annealing temperature and time.

Solvent Removal/Film Formation

Solvent can be removed from the ink compositions, and films can be formed. Solid films can be formed that either comprise solvent, are substantially free of solvent, or are free of solvent. For example, the amount of remaining solvent can be less than about 5% by weight, or less than about 1% by weight, or less than about 0.1% by weight.

Conventional methods can be used to cast polymer materials from the compositions to provide solid forms, including thin film forms and printed forms. For example, the conjugated polymers can be dissolved or dispersed in the first and second (and any additional) solvents then coated onto a substrate and allowed to dry. Suitable coating methods are known. These include roll coating, screen printing, spin casting, spin coating, doctor blading, dip coating, spray coating, or ink jet printing, and other known coating and printing methods. Other methods are described in the references cited herein.

The thickness of the film coated onto the substrate can be, for example, about 10 nm to about 500 μm, or about 50 nm to about 250 nm, or about 100 nm to about 200 nm.

Optionally, the resulting films may be thermally annealed as desired. Annealing is preferably carried out in an inert (e.g., Ar or N₂) atmosphere. Annealing temperature and time can be adjusted to achieve a desired result. Annealing temperature can be for example about 50° C. to about 200° C., or about 130° C. to about 180° C. The annealing temperature can be below the melting temperature of the conjugated polymer. The annealing temperature can be, for example, below, at, or above the glass transition temperature of the conjugated polymer. The annealing temperature can be, for example, about 5° C. to about 60° C. above the glass transition temperature.

The resulting polymer materials can be characterized by improved electronic or optoelectronic properties, due to improved morphology. In some instances the improved morphology is evidenced through a higher degree of polymer-polymer intermixing and intermolecular and/or intramolecular order, which may in turn be evidenced through a bathochromic shift of the absorption maximum of the UV-visible-NIR spectrum of the material and/or through more resolved fine vibronic structure in the electronic absorption spectrum of the material.

When the materials are used as the active layer in a photovoltaic cell, they typically exhibit higher absorption of solar radiation, increased current density values and/or higher power conversion efficiencies than active materials made using the same methods and compositions with the exception that the solvent system from the which latter materials are made does not include the second solvent.

### Electronic Devices

Examples of devices into which the present polymer materials may be incorporated include, but are not limited to, organic photovoltaic cells, photoluminescent devices (e.g., organic light emitting diodes), and transistors.

### Solar Cells

A conductive polymer solar cell can be fabricated in a variety of embodiments known in the art and can, for example, comprise five components. A transparent electrode such as indium tin oxide (ITO) coated onto plastic or glass can function as the anode. It can be approximately 100 nm thick and allow light to enter the solar cell. The anode can be coated with up to 100 nm of a hole injection layer (HIL). The HIL can planarize the ITO surface and facilitate the collection of positive charge carriers (holes) from the light-harvesting layer to the anode. The opposite electrode, or cathode, can be made of a metal such as calcium or aluminum, and is typically for example 70 nm thick or more. It may include a thin conditioning layer (e.g., less than 1 nm of lithium fluoride) that can increase lifetime and performance. In some cases, the cathode may be coated onto a supporting surface such as a flexible plastic or glass sheet. This electrode can carry electrons out of the solar cell and complete the electrical circuit.

The polymer materials may be used as the active layer of the solar cell, which is disposed between the hole injection layer and the cathode. There can be a junction between the conjugated polymer and n-type components (as described above) in the active layer. The conjugated material (i.e., the p-type material) is often referred to as the light harvesting component. This material can absorb photons (light) which excite an electron from its ground state to an excited energy state, leaving behind a positive charge or “hole.” This electron-hole combination can be bound together, forming what is called an “exciton.” The exciton can diffuse to a junction between the p-type and n-type materials, where the charge can then be separated. The electron and “hole” charges can be conducted through the n-type and p-type materials, respectively, to the electrodes resulting in the flow of electric current out of the cell.

In one embodiment, both the active layer and the hole injection layer of the photovoltaic cell can comprise polythiophenes, preferably regioregular polythiophenes.

### Electroluminescent Devices

A typical electroluminescent device comprises four components. Two of these components are electrodes. The first can be a transparent anode such as indium tin oxide, coated onto a plastic or glass substrate, which functions as a charge carrier and allows emission of the photon from the device by virtue of its transparency. The second electrode, or cathode, is frequently made of a low work function metal such as calcium or aluminum or both. In some cases this metal may be coated onto a supporting surface such as a plastic or glass sheet. This second electrode conducts or injects electrons into the device. Between these two electrodes are the electroluminescent layer (“EL”) and the hole injection layer (“HIL”) or hole transport layer (“HTL”).

The EL can comprise, for example, materials based on polyphenylene vinylenes, polyfluorenes, and organic-transition metal small molecule complexes. The present conjugated polymers could also be incorporated into the EL. These materials are generally chosen for the efficiency with which they emit photons when an exciton relaxes to the ground state through fluorescence or phosphorescence and for the wavelength or color of the light that they emit through the transparent electrode.

The present conjugated polymer material may be used as an HIL and/or an HTL. These are conducting materials that facilitate transfer of the positive charge or “hole” from the transparent anode to the EL, creating the exciton which in turn leads to light emission.

The electroluminescent devices can take a variety of forms. The present devices, which comprise electroluminescent polymers, are commonly referred to as PLEDs (Polymer Light Emitting Diodes). The EL layers can be designed to emit white light, either for white lighting applications or to be color filtered for a full-color display application. The EL layers can also be designed to emit specific colors, such as red, green, and blue, which can then be combined to create the full spectrum of colors as seen by the human eye.

### Thin Film Transistors

A typical thin film transistor include a substrate, source and drain electrodes disposed over the substrate, a semiconductor layer including the present conjugated polymer materials, disposed over the source and drain electrodes and the substrate, an insulating layer disposed over the conjugated polymer layer, and a gate electrode disposed over the insulating layer. However, this description is intended only to illustrate one embodiment of a typical thin film transistor; other configuration are possible, as well-known in the art.

The following references can be used in practicing the various embodiments of the claimed inventions: (1) Brabec, et al., Adv. Func. Mater. 2001, 11, 374-380; (2) Sariciftci, N. S., Curr. Opinion in Solid State and Materials Science, 1999, 4, 373-378; (3) Sariciftci, N., Materials Today 2004, 36; (4) Hoppe, H.; Sariciftci, N. S., J. Mater. Res. 2004, 19, 1924, (5) Nakamura, et al., Applied Physics Letters, 87, 132105 (2005); (6) Paddinger et al., Advanced Functional Materials, 2003, 13, No. 1, January, 85; (7) Kim, et al., Photovoltaic Materials and Phenomena Scell—2004, 1371, (8) J. Mater. Res., Vol. 20, No. 12, Dec. 2005, 3224; (9) Inoue, et al., Mater. Res. Soc. Symp. Proc., vol. 836, L.3.2.1; (10) Li et al., J. Applied Physics, 98, 043704 (2005).

Electrostatic Dissipation Coatings

Electrostatic dissipation coatings are described in for example U.S. provisional patent application Ser. No. 60/760,386 filed Jan. 20, 2006 to Greco et al., which is hereby incorporated by reference in its entirety including figures, claims, and working examples.

In one embodiment, the polymer materials as described and claimed herein are employed in or as electrostatic dissipation (ESD) coatings, packaging materials, and other forms and applications. Electrostatic discharge is a common problem in many applications including electronic devices which are becoming smaller and more intricate. To combat this undesired event, conductive coatings, also known as ESD coatings, can be used to coat numerous devices and device components. Conductive materials can be also blended into other materials such as polymers to form blends and packaging materials. The polymer materials described herein may be used as the only polymeric component of an ESD coating or be combined (i.e., blended) with one or more additional polymers.

A non-limiting example of this embodiment involves a device comprising an electrostatic dissipation (ESD) coating, said ESD coating comprising at least one conjugated polymer, wherein the coating has been cast from a composition comprising at least a first solvent and a second solvent as described herein. In another embodiment, provided is an ESD packaging material.

The coating may be a blend of one or more polymers. In these ESD coatings, where a polymeric blend is used, the polymers are preferably compatible and soluble, dispersible or otherwise solution processable in the solvent system as described herein. Thus, in addition to the at least once conjugated polymer, the coating may include one or more additional polymers. The polymer can be a synthetic polymer and is not particularly limited. It can be for example thermoplastic. Examples include organic polymers, synthetic polymers or oligomers, such as a polyvinyl polymer having a polymer side group, a poly(styrene) or a poly(styrene) derivative, poly(vinyl acetate) or its derivatives, poly(ethylene glycol) or its derivatives such as poly(ethylene-co-vinyl acetate), poly(pyrrolidone) or its derivatives such as poly(1-vinylpyrrolidone-co-vinyl acetate, poly(vinyl pyridine) or its derivatives, poly(methyl methacrylate) or its derivatives, poly(butyl acrylate) or its derivatives. More generally, it can comprise of polymers or oligomers built from monomers such as CH₂CH Ar, where Ar=any aryl or functionalized aryl group, isocyanates, ethylene oxides, conjugated dienes, CH₂CHR₁R (where R₁=alkyl, aryl, or alkylaryl functionality and R═H, alkyl, Cl, Br, F, OH, ester, acid, or ether), lactam, lactone, siloxanes, and ATRP macroinitiators. Preferred examples include poly(styrene) and poly(4-vinyl pyridine). Another example is a water-soluble or water-dispersable polyurethane.

The molecular weight of the polymers in the coating can vary. In general, for example, the number average molecular weight of the polymers can be between about 5,000 and about 50,000. If desired, the number average molecular weight of the polymers can be for example about 5,000 to about 10,000,000, or about 5,000 to about 1,000,000.

In any of the aforementioned ESD coatings, at least one polymer may be cross-linked for various reasons such as improved chemical, mechanical or electrical properties.

For proper dissipation of static electricity the conductivity of the coating can be tuned. For example, the amount of conjugated polymer can be increased or decreased. In addition, in some cases, doping can be used.

Application of the ESD coating can be achieved via spin coating, ink jetting, roll coating, gravure printing, dip coating, zone casting, or a combination thereof. Normally the applied coating is greater than 10 nm in thickness. Often, the coating is applied to insulating surfaces such as glass, silica, polymer or any others where static charge builds up. Additionally, the polymer material can be blended into materials used to fabricate packaging film used for protection of for example sensitive electronic equipment. This may be achieved by typical processing methodologies, such as, for example, blown film extrusion. Optical properties of the finished coating can vary tremendously depending on the type of blend and percent ratio of the polymers. Preferably, transparency of the coating is at least 90% over the wavelength region of 300 nm to 800 nm.

The ESD coatings can be applied to a wide variety of devices requiring static charge dissipation. Non-limiting examples include: semiconductor devices and components, integrated circuits, display screens, projectors, aircraft wide screens, vehicular wide screens or CRT screens.

Device Improvements

The use of the second solvent comprising a heterocyclic ring can provide improved device performance. For example, performance can be compared to the performance in a control device which is substantially the same apart from the use of a second solvent comprising a heterocyclic ring.

In solar cells, for example, parameters such as J_{sc} (mA/cm²), V_{oc}, FF, and efficiency (η) can be improved compared to a control which utilizes a single solvent (i.e., the first solvent), wherein the control has the same film thickness. For example, an efficiency improvement of at least about 5% can be observed; or an efficiency improvement of at least about 10%, or an efficiency improvement of at least about 15%; or an efficiency improvement of about 5% to about 50%. In addition, a current density improvement of at least about 5% can be observed; or a current density improvement of at least about 10%, or a current density improvement of at least about 15%; or a current density improvement of about 5% to about 50%.

Other examples of devices include sensors and shielding layers.

In addition to the description provided above, the following non-limiting examples are provided.

### WORKING EXAMPLES

### Example 1

### Polymer Film

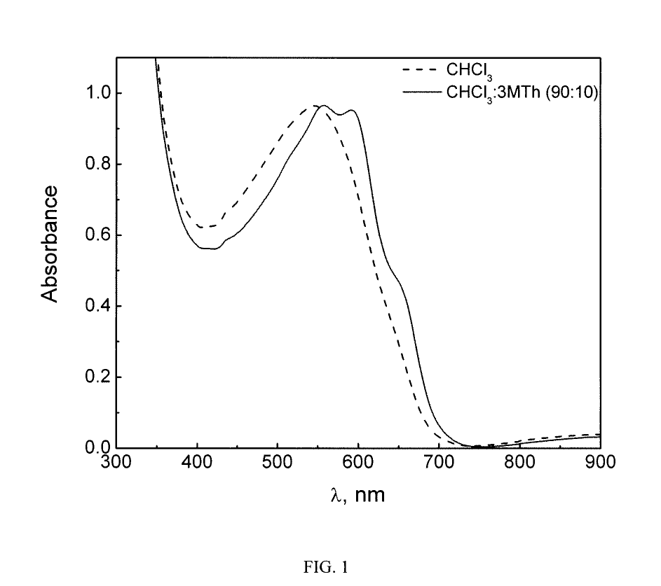

Poly[3-(4-octylphenyl)thiophene]polymer films were spin cast from two solvent systems. The first solvent system was a single solvent system of CHCl₃. The second solvent system included CHCl₃ as a first solvent and 3-methyl thiophene as a second solvent at a volume ratio of 90:10. The films were cast on substrates and allowed to dry with annealing at 70° C. for 30 minutes to provide films having the same thickness. The UV-Vis-NIR spectra for the two films are shown in FIG. 1. The UV-vis-NIR data were collected using a Varian Cary 5000 Spectrophotometer and Cary Win software. FIG. 1 clearly shows a bathochromic shift for the material cast from the co-solvent blend (solid line, λₘₐₓ=558 nm) relative to the material cast from the single solvent (dash line, λₘₐₓ=545 nm).

The observed bathochromic shift is evidence of improved polymer chain organization.

### Example 2

### Photovoltaic Devices

Photovoltaic devices incorporating conjugated polymer active layers made in accordance with the present methods were fabricated. The devices included: (1) a patterned indium tin oxide (ITO) anode (601/square) on glass substrate (purchased from Thin Film Devices (located in Anaheim, Calif.)); (2) a thin layer of HIL (30 nm thick) composed of PEDOT/PSS ((Baytron AI 4083) purchased from HC Stark); (3) a 100 nm layer active layer of poly(3-hexylthiophene (P3HT) (purchased from Plexcore) blended with an n-type component (i.e., the electron acceptor), which was either methanofullerence [6,6]-phenyl C₆₁-butyric acid methyl ester (PCBM) (purchased from Nano-C, located in Westwood, Mass.), C₅₀-Indene mono adduct, or C₆₀-indene bis-adduct; and (4) and a Ca/Al bilayer cathode. The P3HT was prepared as described in Loewe, et al. Adv. Mater. 1999, 11, 250-253 using 2,5-dibromo-3-hexylthiophene in place of 2,5-dibromo-dodecylthiophene, and using 0.0028 eq of Ni(dppp)Cl₂ instead of 0.01 eq; 69K molecular weight as measured by GPC using chloroform as eluent, 1.35 PDI.

The patterned ITO glass substrates were cleaned with detergent, hot water and organic solvents (acetone and alcohol) in an ultrasonic bath and treated with ozone plasma immediately prior to device layer deposition. The HIL solution was then spin coated on the patterned ITO glass substrate to achieve a thickness of 30 nm. The film was dried at 150° C. for 30 minutes in a nitrogen atmosphere. The formulations for the active layers are provided in Table 1, below. A control device was fabricated by depositing a P3HT/PCBM blend from dichlorobenzene. The p/n ratio of the blend for the control was 1.2:1. Formulation was made to 0.024% volume solids for each system and was then spun on the top of the HIL film with no damage to the HIL (verified by AFM). The film was then annealed at 175° C. for 30 minutes in a glove box. Next, a 5 nm Ca layer was thermally evaporated onto the active layer through a shadow mask, followed by deposition of a 150 nm Al layer. The devices were then encapsulated via a glass cover slip (blanket) encapsulation sealed with EPO-TEK OG112-4 UV curable glue. The encapsulated device was cured under UV irradiation (80 mW/cm²) for 4 minutes and tested as follows.

The photovoltaic characteristics of devices under white light exposure (Air Mass 1.5 Global Filter) were measured using a system equipped with a Keithley 2400 source meter and an Oriel 300W Solar Simulator based on a Xe lamp with output intensity of 100 mW/cm² (AM1.5G). The light intensity was set using an NREL-certified Si-KG5 silicon photodiode. UV-vis-NIR data were collected suing a Varian Cary 5000 Spectrophotometer and Cary Win software.

The power conversion efficiency of a solar cell is given as η=(FF|J_{sc}|V_{oc})/Pᵢₙ, where FF is the fill factor, J_{sc} is the current density at short circuit, V_{oc} is the photovoltage at open circuit and Pᵢₙ is the incident light power density. The J_{sc}, V_{oc} and efficiency measured for each device are shown in Table 1, below, compared to the control device which was made as described above using PCBM as the n-type component with poly(3-hexylthiophene) from dichlorobenzene.

TABLE 1

| | | | | Solvent | J_{SC} | | | | % |
|---|---|---|---|---|---|---|---|---|---|
| Conjugated | n-type | p/n | Solvent | Blend | mA/ | | | | Increase |
| Polymer¹ | Component | ratio | Blend | Ratio | cm² | V_{OC} | FF | η(%) | in η³ |
| P3HT | PCBM | 1.2:1 | DCB | 100 | 8.80 | 0.58 | 0.58 | 2.92 | — |
| P3HT | PCBM | 1.2:1 | DCB/ | 75:25 | 9.87 | 0.57 | 0.55 | 3.07 | 5 |
| | | | 3MTH | | | | | | |
| P3HT | C60-bis | 1.2:1 | DCB | 100 | 8.37 | 0.82 | 0.66 | 4.5 | — |
| | indene | | | | | | | | |
| | adduct | | | | | | | | |
| P3HT | C60-bis | 1.2:1 | DCB/ | 75:25 | 9.48 | 0.82 | 0.63 | 4.9 | ~9 |
| | indene | | 3MT | | | | | | |
| | adduct | | | | | | | | |
| P3HT* | C60-bis | 1.2:1 | DCB/ | 75:25 | 9.43 | 0.84 | 0.64 | 5.1 | ~13 |
| | indene | | 3MT | | | | | | |
| | adduct | | | | | | | | |

DCB = dichlorobenzene;
3MTH = 3-methyl thiophene;
¹Regioregular poly(3-hexylthiophene) (P3HT) was synthesized via the GRIM methodology and its absolute molecular weight (Mₙ) was determined using ¹H NMR spectroscopy [Iovu, M. C. et al. Macromolecules 2005, 38, 8649.]: Mₙ(P3HT) = 26,600; Mₙ(P3HT*) = 33,000
³% Increase in organic solar cell efficiency (η %) was calculated in respect to a control OPV device (entrées 1 and 3 in the table) fabricated with a single non-heterocyclic solvent.

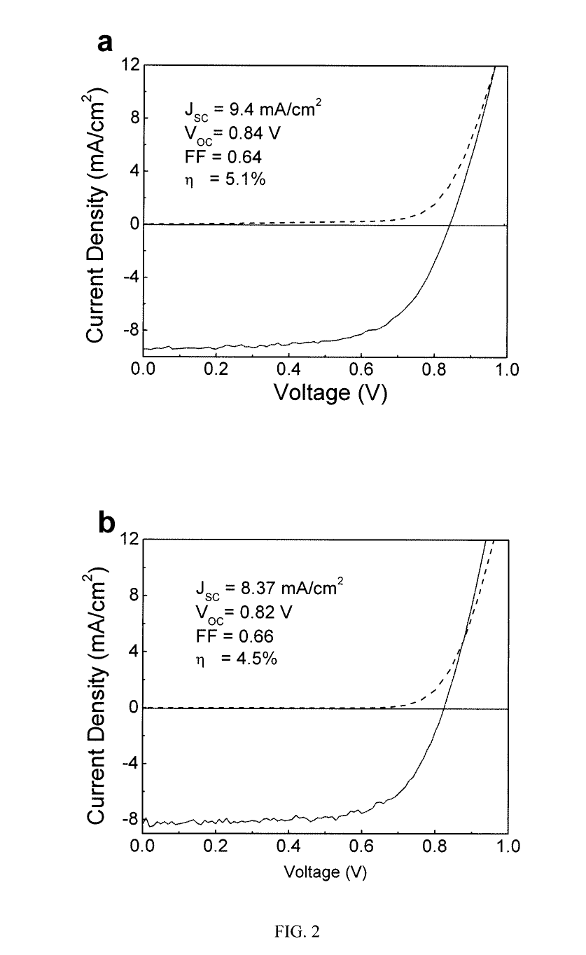

The results above indicate that photovoltaic devices incorporating conjugated polymers made using the present solvent systems have power conversion efficiencies at least 11% greater than corresponding photovoltaic devices made from a single solvent system. The enhanced organization of polymer chains also improves charge transport (hole conduction) in conjugated polymers thereby increase solar cell device efficiency. As shown in the table, power conversion efficiencies (η%) as high as 5.1% were achieved in organic solar cells fabricated with poly(3-hexylthiophene) (P3HT) and a soluble fullerene derivative as the active layer cast from a solvent blend that combines at least one solvent comprising a heterocyclic ring and is different from the first solvent. The I-V characteristics of the two OPV devices is shown in FIG. 2.

The following non-limiting embodiments are provided by way of illustration only:

One embodiment of the present invention provides a composition comprising at least one conjugated polymer, at least one first solvent, and at least one second solvent, wherein the second solvent is different from the first solvent, wherein the second solvent comprises a heterocyclic ring, and further wherein the volume ratio of second solvent to first solvent is less than about 1:1. In this embodiment, the conjugated polymer can comprise at least one backbone repeat unit comprising a heterocyclic ring, which can be a thiophene ring. For example, the conjugated polymer can comprise a regioregular polythiophene derivative, such as, a regioregular poly(3-alkyl thiophene), a regioregular poly(3-aryl thiophene) (e.g., a regioregular poly(3-aryl thiophene), wherein the aryl group at the 3-position is substituted with an alkyl group), or a regioregular poly(3-alkoxy thiophene).

The heterocyclic ring in this embodiment can comprise at least one atom selected from S atoms, O atoms, and N atoms or at least one S atom or at least one O atom. For example, the heterocyclic ring can be a thiophene ring and, more specifically, can be an alkylthiophene.

In one version of this embodiment, the conjugated polymer comprises at least one backbone repeat unit comprising a heterocyclic ring, and the heterocyclic ring in the backbone repeat unit and the heterocyclic ring in the second solvent are the same. For example, the conjugated polymer can comprise a polythiophene and the second solvent can comprise a thiophene.

The first solvent in this embodiment can comprise an aromatic compound, such as, but not limited to, a halogenated aromatic compound. Non-limiting examples of first solvents include, but are not limited to, chlorobenzene, o-dichlorobenzene, trichlorobenzene, chloroform, o-xylene, and toluene.

The volume ratio of second solvent to first solvent in this embodiment can be less than about 1:2. This includes embodiments wherein The composition of embodiment 1, wherein a volume ratio of second solvent to first solvent is less than about 1:3.

In this embodiment of the invention, the composition can optionally further comprise an electron accepting moiety. Fullerene and fullerene derivative are examples of suitable electron accepting moieties. The weight ratio of conjugated polymer to electron acceptor molecule can be, for example, about 1:2 to 2:1.

In this embodiment, the composition can comprise, for example, about 1 vol. % solids or less. This includes compositions that comprises about 0.1 vol. % solids or less.

In one specific, non-limiting, version of this embodiment, the conjugated polymer can comprise a polythiophene, the first solvent can comprise an aromatic solvent, the second solvent can comprise a thiophene, and the composition can further comprise an n-acceptor moiety. For example, the conjugated polymer can comprise a regioregular polythiophene, a halogenated aromatic solvent, an alkylthiophene, and a fullerene derivative.

Another embodiment of the present invention provides a composition comprising at least one conjugated polymer comprising a backbone repeat unit comprising a first heterocyclic ring, at least one first solvent, and at least one second solvent, wherein the second solvent is different from the first solvent and the second solvent comprises a second heterocyclic ring, wherein the first heterocyclic ring and the second heterocyclic ring are the same. For example, the first heterocyclic ring and the second heterocyclic ring can each be thiophene rings, including thiophene rings comprising an alkyl substituent and the conjugated polymer can comprise a regioregular polythiophene derivative homopolymer or copolymer.

In this embodiment, the composition can further comprise at least one electron accepting moiety, such as, but not limited to, a fullerene.

The volume amount of first solvent can be greater than the volume amount of second solvent in this embodiment. The boiling point of the first solvent can be higher than the boiling point of the second solvent in this embodiment.

In a version of this embodiment, the first solvent comprises a halogenated aromatic compound and the second solvent comprise 3-methylthiophene. For example, the conjugated polymer can comprise a polythiophene, the first solvent comprises a halogenated aromatic compound and the second solvent comprise 3-methylthiophene. The composition can further comprise a fullerene moiety.

In yet another embodiment, the present invention provides a composition comprising at least one soluble conjugated polymer, at least one first solvent for the soluble conjugated polymer, the first solvent having a boiling point of about 150° C. to about 210° C., at least one second solvent which comprises a heterocyclic ring and is different from the first solvent and has a boiling point of about 85° C. to about 145° C. The resulting composition can be capable of functioning as a solar cell active layer upon solvent removal.

In one version of this embodiment, the composition can comprise at least two second solvents and/or at least two first solvents. In addition, the composition can comprise an electron accepting moiety, such as a fullerene or a fullerene derivative, examples of which include methanofullerene [6,6]-phenyl C₆₁-butyric acid methyl ester, C₆₀-indene mono adduct, C₆₀-indene bis-adduct, and combinations thereof.

In one specific, non-limited version of this embodiment, the conjugated polymer comprises a polythiophene (e.g., at least one regioregular polythiophene) and the second solvent comprises a thiophene compound.

Yet another embodiment of the present invention provides a method for forming an active layer of an electronic device, the method comprising, applying a composition comprising a conjugated polymer, a first solvent, and a second solvent comprising a heterocyclic ring to the surface of a substrate of the electronic device, wherein the second solvent is different from the first solvent, and further wherein the volume ratio of the second solvent to the first solvent is less than about 1:1. The method can further include the step of removing solvent to form a solid active layer and can still further include the step of thermally annealing the active layer. The electronic device incorporating the active layer can be, for example, a solar cell, a light-emitting diode or a transistor.

Still anther embodiment of the invention provides a method for forming a material comprising a conjugated polymer, the method comprising applying a composition comprising a conjugated polymer and a solvent system comprising at least one first solvent and at least one second solvent to a surface and removing the first solvent and the second solvent, wherein the second solvent is different from the first solvent and the second solvent comprises a heterocyclic ring, and further wherein the absorption maximum in the UV-visible-NIR spectrum for the conjugated polymer in the material undergoes a bathochromic shift relative to the absorption maximum in the UV-visible-NIR spectrum for a material made using substantially the same method and the same composition, with the exception that the solvent system does not include the second solvent.

A method for improving an ink for printing the active layer of a photovoltaic cell is also an embodiment provided by the present invention. This method uses an ink comprising a conjugated polymer and a first solvent and comprises adding a co-solvent comprising a heterocyclic ring to the ink in an amount sufficient to increase the molecular order of the conjugated polymer in the ink.

Another method provided herein is a method for improving an ink for printing the active layer of a photovoltaic cell, the ink comprising a conjugated polymer and a first solvent, the method comprising adding a co-solvent comprising a heterocyclic ring to the ink in an amount sufficient to increase the efficiency of the active layer by at least 10%.

Yet another method provided herein is a method comprising providing a composition comprising at least one conjugated polymer, at least one first solvent, and at least one second solvent, wherein the second solvent is different from the first solvent, wherein the second solvent comprises a heterocyclic ring, and further wherein the volume ratio of second solvent to first solvent is at less than about 1:1; and forming a film from said composition.

Still another method provided herein is a method comprising providing a composition comprising at least one conjugated polymer comprising a backbone repeat unit comprising a first heterocyclic ring, at least one first solvent, and at least one second solvent, wherein the second solvent is different from the first solvent and the second solvent comprises a second heterocyclic ring, wherein the first heterocyclic ring and the second heterocyclic ring are the same; and forming a film from said composition.

Another method in accordance with the present invention comprises providing a composition comprising at least one soluble conjugated polymer, at least one first solvent for the soluble conjugated polymer which has a boiling point of about 150° C. to about 210° C., at least one second solvent which comprises a heterocyclic ring and is different from the first solvent and has a boiling point of about 85° C. to about 145° C.; and forming a film from said composition.

While some embodiments have been illustrated and described, it should be understood that changes and modifications can be made therein in accordance with ordinary skill in the art without departing from the invention in its broader aspects as defined in the following claims.

What is claimed is:

1. A composition comprising at least one conjugated polymer, at least one first solvent, and at least one second solvent, wherein the second solvent is different from the first solvent, wherein the second solvent comprises a thiophene ring, and further wherein the volume ratio of second solvent to first solvent is less than about 1:1.

2. The composition of claim 1, wherein the conjugated polymer comprises at least one backbone repeat unit comprising a heterocyclic ring.

3. The composition of claim 1, wherein the conjugated polymer comprises at least one backbone repeat unit comprising a thiophene ring.

4. The composition of claim 1, wherein the conjugated polymer comprises a regioregular polythiophene derivative.

5. The composition of claim 1, wherein the conjugated polymer comprises a regioregular poly(3-alkyl thiophene).

6. The composition of claim 1, wherein the conjugated polymer comprises a regioregular poly(3-aryl thiophene).

7. The composition of claim 6, wherein the aryl group at the 3-position is substituted with an alkyl group.

8. The composition of claim 1, wherein the conjugated polymer comprises a regioregular poly(3-alkoxy thiophene).

9. The composition of claim 1, wherein the second solvent is an alkylthiophene.

10. The composition of claim 1, wherein the conjugated polymer comprises a polythiophene.

11. The composition of claim 1, wherein the first solvent comprises an aromatic compound.

12. The composition of claim 1, wherein the first solvent comprises a halogenated aromatic compound.

13. The composition of claim 1, wherein the first solvent is chlorobenzene, o-dichlorobenzene, trichlorobenzene, chloroform, o-xylene, or toluene.

14. The composition of claim 1, wherein a volume ratio of second solvent to first solvent is less than about 1:2.

15. The composition of claim 1, wherein a volume ratio of second solvent to first solvent is less than about 1:3.

16. The composition of claim 1, further comprising an electron accepting moiety.

17. The composition of claim 1, further comprising an electron accepting moiety, wherein the electron accepting moiety comprises a fullerene or a fullerene derivative.

18. The composition of claim 1, wherein the conjugated polymer comprises a polythiophene and the first solvent comprises an aromatic solvent, wherein the composition further comprises an n-acceptor moiety.

19. The composition of claim 1, wherein the conjugated polymer comprises a regioregular polythiophene, the first solvent comprises a halogenated aromatic solvent, and the second solvent comprises an alkylthiophene, and wherein the composition further comprises a fullerene derivative as n-acceptor moiety.

20. A composition comprising at least one conjugated polymer comprising a backbone repeat unit comprising a first heterocyclic ring, at least one first solvent, and at least one second solvent, wherein the second solvent is different from the first solvent and the second solvent comprises a second heterocyclic ring that is the same as the first heterocyclic ring, and further wherein the second solvent is not a halogenated solvent.

21. The composition according to claim 20, wherein the first heterocyclic ring and the second heterocyclic ring are each thiophene rings.

22. The composition according to claim 20, wherein the first heterocyclic ring and the second heterocyclic ring are each thiophene rings, and each thiophene ring comprises an alkyl substituent.

23. The composition according to claim 20, wherein the composition further comprises at least one electron accepting moiety.

24. The composition according to claim 20, wherein the composition further comprises at least one electron accepting moiety comprising a fullerene.

25. The composition according to claim 20, wherein the conjugated polymer comprises a regioregular polythiophene derivative homopolymer or copolymer.

26. The composition according to claim 20, wherein the first solvent comprises a halogenated aromatic compound and the second solvent comprise 3-methylthiophene.

27. The composition according to claim 20, wherein conjugated polymer comprises a polythiophene and the first solvent comprises a halogenated aromatic compound and the second solvent comprise 3-methylthiophene, and the composition further comprises a fullerene moiety.

28. The composition of claim 20, wherein the composition comprises at least two second solvents.

29. The composition of claim 20, wherein the composition comprises at least two first solvents.

30. The composition of claim 20, further comprising an electron accepting moiety comprising at least one mono-, bis-, tris-, or tetra-substituted fullerene, wherein the fullerene is substituted with at least one indene, methanofullerene [6,6]-phenyl C₆₁-butyric acid methyl ester, or a combination thereof.

31. The composition of claim 20, further comprising an electron accepting moiety comprising methanofullerene [6,6]-phenyl C₆₁-butyric acid methyl ester, C₆₀-indene mono adduct, C₆₀-indene bis-adduct, or a combination thereof.

32. A method for forming a layer of an electronic device, the method comprising, applying a composition comprising a conjugated polymer, a first solvent, and a second solvent comprising a thiophene ring to the surface of a substrate of the electronic device, wherein the second solvent is different from the first solvent, and further wherein the volume ratio of the second solvent to the first solvent is less than about 1:1.

33. The method of claim 32, further comprising the step of removing solvent to form a solid layer.

34. The method of claim 32, further comprising the step of removing solvent to form a active layer and further comprising thermally annealing the layer.

35. The method of claim 32, wherein the electronic device is a solar cell.

36. The method of claim 32, wherein the electronic device is a light-emitting diode.

37. The method of claim 32, wherein the electronic device is a transistor.

38. A method for forming a material comprising a conjugated polymer, the method comprising applying a composition comprising a conjugated polymer and a solvent system comprising at least one first solvent and at least one second solvent to a surface and removing the first solvent and the second solvent, wherein the second solvent is different from the first solvent and the second solvent comprises a heterocyclic ring, and further wherein the absorption maximum in the UV-visible-NIR spectrum for the conjugated polymer in the material undergoes a bathochromic shift relative to the absorption maximum in the UV-visible-NIR spectrum for the material made using the solvent system that does not include the second solvent.

39. A method for improving an ink for printing the active layer of a photovoltaic cell, the ink comprising a conjugated polymer and a first solvent, the method comprising adding a second solvent comprising a heterocyclic ring to the ink in an amount sufficient to increase the molecular order of the conjugated polymer in the ink.

40. A method comprising:
providing a composition comprising at least one conjugated polymer comprising a backbone repeat unit comprising a first heterocyclic ring, at least one first solvent, and at least one second solvent, wherein the second solvent is different from the first solvent and the second solvent comprises a second heterocyclic ring that is the same as the first heterocyclic ring, and further wherein the second solvent is not a halogenated solvent;
forming a film from said composition.
